(19) United States
(12) Patent Application Publication
(10) Pub. No.: US 2008/0290416 A1
(43) Pub. Date: Nov. 27, 2008

(54) HIGH-K METAL GATE DEVICES AND METHODS FOR MAKING THE SAME

(75) Inventors: Chen-Hua Yu, Hsin-Chu (TW); Liang-Gi Yao, Shin Chu (TW); Cheng-Tung Lin, Jhudong Township (TW)

Correspondence Address: DUANE MORRIS LLP (TSMC);IP DEPARTMENT, 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/751,403

(22) Filed: May 21, 2007

(51) Int. Cl. H01L 27/092; H01L 21/8238

(52) U.S. Cl. 257/369; 438/216; 257/E27.062; 257/E21.632

(57) ABSTRACT

A layer of P-metal material having a work function of about 4.3 or 4.4 eV or less is formed over a high-k dielectric layer. Portions of the N-metal layer are converted to P-metal materials by introducing additives such as O, C, N, Si or others to produce a P-metal material having an increased work function of about 4.7 or 4.8 eV or greater. A TaC film may be converted to a material of TaCO, TaCN, or TaCON using this technique. The layer of material including original N-metal portions and converted P-metal portions is then patterned using a single patterning operation to simultaneously form semiconductor devices from both the unconverted N-metal sections and converted P-metal sections.

### FIELD OF THE INVENTION

The present invention, relates, most generally to semiconductor devices and methods for forming semiconductor devices. More particularly, the present invention relates to methods and structures for metal gate semiconductor devices with high-k dielectric materials.

### BACKGROUND

In today's rapidly advancing semiconductor manufacturing industry, it is of paramount importance to manufacture the most highly multi-functional and integrated semiconductor devices in the most efficient manner possible. An economy in the number of manufacturing operations used to form a device having a certain level of complexity and integration, is essential for minimizing manufacturing costs and maximizing productivity and throughput.

As device complexities and performance levels increase, high-k dielectric materials are increasingly being used as gate dielectrics for MOSFET (metal oxide semiconductor field effect transistor) devices. When a CMOS (complementary metal oxide semiconductor) device is formed using high-k dielectrics as the gate dielectric materials, different suitable metals must be used as the gate electrode for the PMOS and NMOS transistors. The use of different materials conventionally requires separate deposition and patterning operations. If a single patterning, i.e., etching operation is attempted to be used to etch two dissimilar materials in the same etching operation, at least one of the materials will likely be over- or under-etched and device functionality will suffer or the device will completely fail.

It would therefore be desirable to provide a single layer of material which can be patterned in one etching operation but which can also function as both the N-type metal and P-type metal utilized in conjunction high-k gate dielectric materials and NMOS and PMOS devices, respectively. Such aspect would enable the use of an economical number of processing operations to efficiently produce a CMOS device with N-metal and P-metal devices on the same substrate.

### SUMMARY OF THE INVENTION

To address these and other needs and in view of its purposes, the present invention provides a method for forming PMOS and NMOS semiconductor devices using corresponding P-metal and N-metal materials formed from the same original layer of material and patterned simultaneously. P-metal and N-metal materials refer respectively to materials suitable for use in N-type and P-type semiconductor devices.

According to one aspect, provided is a method for forming a metal gate semiconductor device. The method includes forming an N-metal layer suitable for use as a gate electrode for N-metal semiconductor devices, over a surface of the substrate and converting portions of the N-metal layer to P-metal portions suitable for use as gate electrodes in P-metal semiconductor devices. The method further provides for forming N-metal semiconductor devices using unconverted sections of the N-metal layer and P-metal semiconductor devices using sections of the P-metal portions.

According to another aspect, provided is a CMOS device disposed over a substrate and including at least one NMOS semiconductor device comprising a portion of a layer of TaC and at least one PMOS semiconductor device comprising a further portion of the layer of TaC. The further portion includes at least one of O, C, N and Si as an impurity added therein.

According to yet another aspect, provided is a CMOS device disposed over a substrate and comprising at least one NMOS transistor having a gate formed of a portion of a layer of binary material having a work function of about 4.5 eV or less and at least one PMOS transistor having a gate formed of a further portion of the layer of binary material and having a work function of about 4.7 eV or greater. The further portion includes at least one of O, C, N and Si as an impurity added therein.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIGS. 1-5 are cross-sectional views showing a sequence of processing operations used to form N-metal and P-metal devices according to an exemplary aspect of the invention.

### DETAILED DESCRIPTION

The present invention provides for forming P-metal sections from an original N-metal layer and for forming both P-type semiconductor devices and N-type semiconductor devices from the original N-metal layer, the P-type semiconductor devices formed of material sections that are converted from N-metal materials to P-metal materials.

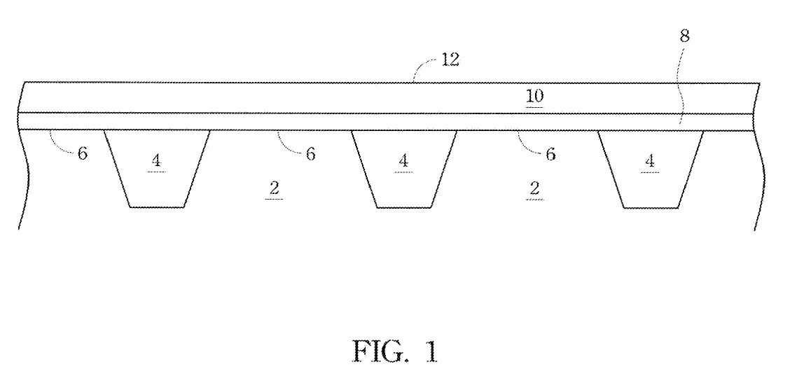

FIG. 1 is a cross-sectional view showing substrate 2 which may be a conventional semiconductor substrate formed of various suitable semiconductor materials such as but not limited to silicon. Isolation devices 4 are formed extending downwardly into semiconductor substrate 2 from surface 6. Isolation devices 4 may be shallow trench isolation (STI) devices or other devices suitable for electrically isolating substrate regions from one another. High-k dielectric layer 8 is formed over surface 6 of semiconductor substrate 2 and may be formed of various suitable high-k dielectric materials. Suitable high-k dielectric materials include but are not limited to various silicon oxides, silicon nitrides and silicon oxynitrides or high-k dielectric materials such as lanthanum oxide, La₂O₃, aluminum oxide, Al₂O₃, hafnium oxide, HfO₂, hafnium oxynitride, HfON, or zirconium oxide, ZrO₂, but other suitable gate dielectric materials formed of high-k dielectrics having a permittivity of greater than 5 relative to free space, may be used in other exemplary embodiments. High-k dielectric layer 8 may be dimensioned according to device requirements. High-k dielectric layer 8 may be formed to a thickness suitable for use in NMOS and PMOS semiconductor devices such as N-type and P-type MOSFETs (metal oxide semiconductor field effect transistors).

Layer 10 is formed over high-k dielectric layer 8 and includes upper surface 12. Layer 10 is advantageously an N-metal material suitable for use as a gate electrode in N-type semiconductor devices such as NMOS transistors i.e., layer 10 has a work function of about 4.3 or 4.4 electron volts, eV. Layer 10 may be formed of ruthenium, TaC, TaN, or various other suitable binary N-metal materials. Typical thicknesses for layer 10 may be about 1.0 to 2.0 nm, but other suitable thicknesses may be used in other exemplary embodiments. Each of the aspects and features shown in FIG. 1 may be formed using conventional methods.

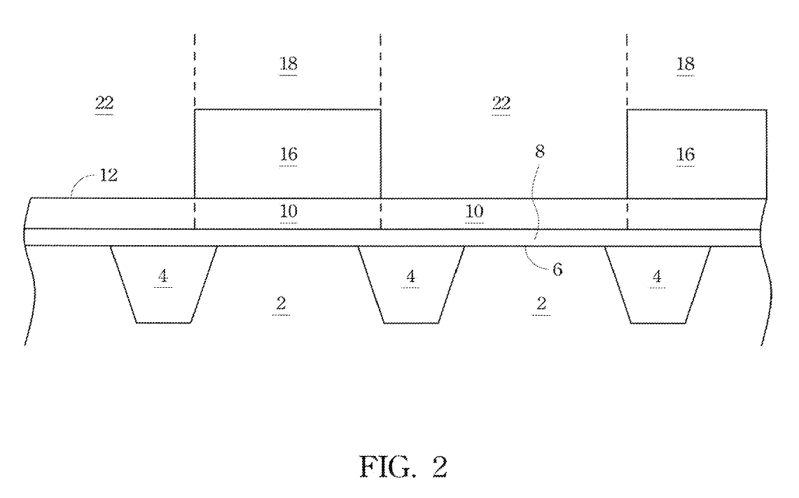

Now turning to FIG. 2, a removable layer is formed over upper surface 12 of layer 10 and patterned into discrete portions. Pattern sections 16 represent portions of the removable layer that remain over layer 10 after the removable layer has been patterned. The removable layer may be formed of photoresist, polysilicon, silicon dioxide, or other suitable oxides or other materials. Conventional methods may be used to form pattern sections 16 from a layer of the removable layer formed entirely over upper surface 12 of layer 10. Pattern sections 16 are formed in N-metal sections 18 in which N-type devices will be formed and in which layer 10 will remain an unconverted N-metal material. P-metal sections 22 represent the areas void of pattern sections 16 and within which P-type devices will be formed and in which layer 10 will be converted to a P-metal layer. With pattern sections 16 in place within N-metal sections 18, various methods can be used to convert exposed portions of layer 10 from an N-metal material to a P-metal material.

Materials such as oxygen, O, nitrogen, N, carbon, C, and/or silicon, Si, may be implanted or otherwise introduced into the exposed sections of layer 10, i.e., the portions of layer 10 within P-metal sections 22. In one exemplary embodiment, ion implantation may be used. In another exemplary embodiment, gas cluster ion beam (GCIB) implantation techniques may be used and in yet another exemplary embodiment, diffusion may be used to drive the desired additives/impurities into the exposed portions of layer 10, with pattern sections 16 preventing the additive/impurity from being introduced into layer 10 within N-metal sections 18. The addition of additives changes the work function of layer 10 from about 4.3 or 4.4 electron volts or less as deposited, to about 4.7 or 4.8 electron volts or greater after conversion. Other work functions may be used in other exemplary embodiments but an aspect of the invention is that original layer 18 is now a layer that has portions with different (relatively high/relatively low) work functions, with the converted P-metal sections having an increased work function.

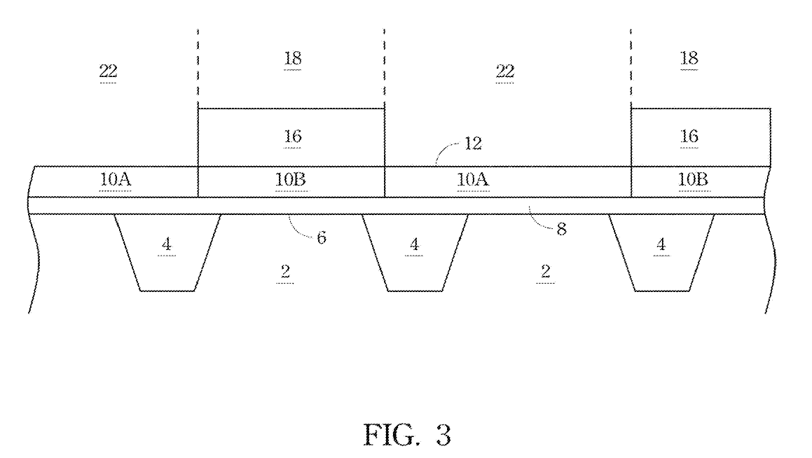

FIG. 3 shows the structure of FIG. 2 after the operation that converts uncovered sections of layer 10 shown in FIGS. 1 and 2, to a P-metal material. Converted sections 10A, within P-metal sections 22, are P-metal materials having relatively high work functions, i.e., about 4.7 or 4.8 eV or greater, while unconverted sections 10B remain the originally-formed layer 10 material, an N-metal material having a work function of about 4.3 or 4.4 eV or less. According to one exemplary embodiment in which original layer 10 is TaC, converted sections 10A may be TaCO, TaCN, or TaCON, with unconverted sections 10B remaining TaC. According to another exemplary embodiment in which layer 10 is ruthenium, converted sections 10A may be ruthenium oxide, RuO, with unconverted sections 10B remaining ruthenium. According to another exemplary embodiment in which original layer 10 is TaN, converted sections 10A may be TaON or TaSiN. These film layer details are intended to be exemplary only and other materials may be used in other exemplary embodiments. According to one general description, layer 10 may be a binary material represented by XY and being a generally N-metal material with a work function of about 4.3 or 4.4 eV or less and may be converted to converted sections 10A which may be represented by the oxide, nitride or oxynitride version of the binary material, XYON, XYN, or XYO. According to yet another exemplary aspect in which carbon is added as an impurity into layer 10, the additional carbon content may convert the original N-metal material to a P-metal material having a greater work function.

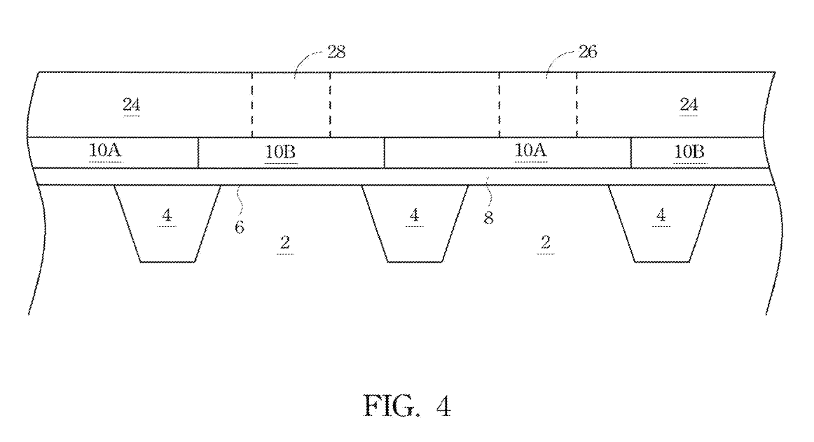

FIG. 4 shows the structure of FIG. 3 after removable layer 16 has been removed using conventional methods and after patterning layer 24 has been formed over converted sections 10A and unconverted sections 10B of layer 10. A further patterning operation is then used to simultaneously form pattern sections 26 and 28 over converted section 10A and unconverted section 10B formed in P-metal section 22 and N-metal section 18, respectively.

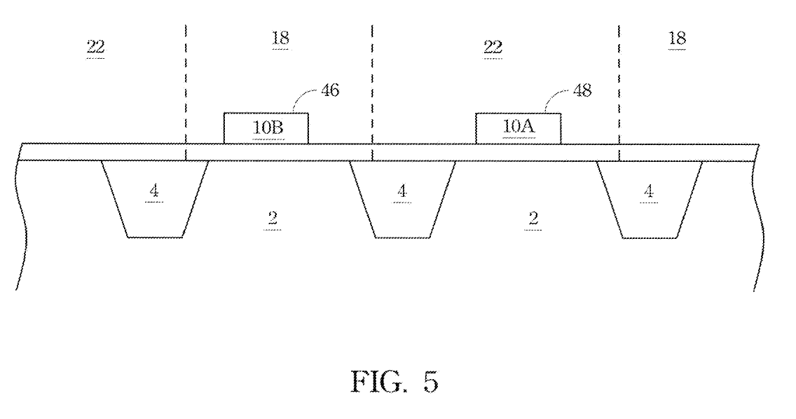

A conventional patterning and etching operation may be used to form discrete sections 46 and 48 shown in FIG. 5. Discrete section 46 is formed of unconverted section 10B which is an N-metal material and therefore discrete section 46 may be used to form the gate electrode of an N-type semiconductor device such as an N-type MOSFET. Discrete section 48 formed of converted section 10A, a P-metal material, may serve as a P-metal structure in a semiconductor device such as the gate for a PMOS transistor, for example a P-type MOSFET. In this manner, P-type metal gate transistors and N-type metal gate transistors, each with high-k gate dielectrics, are formed. Such applications are intended to be exemplary only and in other exemplary embodiments, converted sections 10A and unconverted sections 10B may be simultaneously patterned to form P-metal and N-metal structures, respectively, that may be used in various other applications.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the device be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for forming a semiconductor device comprising:
forming an N-metal layer suitable for use as a gate electrode for N-metal semiconductor devices, over a surface of a substrate;
converting portions of said N-metal layer to P-metal portions suitable for use as gate electrodes in P-metal semiconductor devices; and
forming N-metal semiconductor devices using unconverted sections of said N-metal layer and P-metal semiconductor devices using sections of said P-metal portions.

2. The method as in claim 1, wherein said N-metal layer comprises one of TaC and TaN.

3. The method as in claim 1, wherein said N-metal layer includes a work function of about 4.4 eV or less.

4. The method as in claim 3, wherein said converting comprises said P-metal sections having a work function of about 4.8 eV or higher.

5. The method as in claim 1, wherein said converting comprises adding at least one of C, O, N and Si to said N-metal layer to convert said portions of said N-metal layer to said P-metal portions.

6. The method as in claim 5, wherein said adding comprises one of ion implantation, diffusion and GCIB (gas cluster ion beam) implantation.

7. The method as in claim 1, wherein said converting comprises forming a patterned removable layer over said N-metal layer, said portions comprise portions of said N-metal layer that are not covered by said patterned removable layer, and further comprising removing said patterned removable layer after said converting.

8. The method as in claim 7, wherein said removable layer comprises a layer of one of photoresist, polysilicon and an oxide.

9. The method as in claim 1, wherein said forming N-metal semiconductor devices and P-metal semiconductor devices comprises simultaneously etching said unconverted portions of said N-metal layer and said P-metal portions.

10. The method as in claim 1, wherein said N-metal layer comprises TaC and said converting includes said P-metal portions comprising one of TaCO, TaCON and TaCN.

11. The method as in claim 1, wherein said N-metal layer comprises a binary material represented by XY and said converting includes said P-metal portions comprising one of XY oxide or XY nitride or XY oxynitride.

12. The method as in claim 1, wherein said forming N-metal semiconductor devices comprises forming at least an N-type metal gate MOSFET and said forming P-metal semiconductor devices comprises forming at least one P-type metal gate MOSFET.

13. The method as in claim 1, wherein said forming an N-metal layer comprises forming said N-metal layer over a high-k dielectric formed over said surface, said forming N-metal semiconductor devices and said forming P-metal semiconductor devices includes using said high-k dielectric as a gate dielectric and said N-metal semiconductor devices and said P-metal semiconductor devices each comprise metal gate transistors.

14. The method as in claim 1, wherein said N-metal layer comprises ruthenium and said converting portions comprises oxidizing to convert said ruthenium to RuO.

15. A CMOS device disposed over a substrate and comprising:
at least one NMOS semiconductor device comprising a portion of a layer of TaC; and
at least one PMOS semiconductor device comprising a further portion of said layer of TaC, said further portion including at least one of O, C, N and Si as an impurity added therein.

16. The CMOS device as in claim 15, wherein said portion includes a work function of about 4.4 eV or less and said further portion includes a work function of about 4.8 eV or greater.

17. The CMOS device as in claim 15, wherein said NMOS semiconductor device comprises an NMOS metal gate transistor having said metal gate formed of said portion of said layer of TaC and disposed over a high-k gate dielectric formed over a surface of said substrate, and said PMOS semiconductor device comprises a PMOS metal gate transistor having said metal gate formed of said further portion of said layer of TaC disposed over said high-k gate dielectric.

18. A CMOS device disposed over a substrate and comprising:
at least one NMOS transistor having a gate formed of a portion of a layer of binary material having a work function of about 4.5 eV or less; and
at least one PMOS transistor having a gate formed of a further portion of said layer of binary material having a work function of about 4.7 eV or greater, said further portion including at least one of O, C, N and Si as an impurity added therein.

19. The CMOS device as in claim 18, wherein said portion of said layer of binary material comprises TaC and said further portion of said layer of binary material comprises one of TaCO, TaCON and TaCN.

20. The CMOS device as in claim 18, wherein each of said NMOS transistor and said PMOS transistor includes a high-k gate dielectric.
